(19) United States
(12) Patent Application Publication
(10) Pub. No.: US 2011/0058323 A1
(43) Pub. Date: Mar. 10, 2011

(54) Engageable Structure and Engageable Electronic Apparatus Using the Same

(75) Inventors: Chi-Hsiung Lin, Taipei County (TW); Sheng-Cha Hsu, Taipei County (TW)

(73) Assignees: INVENTEC APPLIANCES (SHANGHAI) CO. LTD., Shanghai (CN); INVENTEC APPLIANCES CORP., Taipei County (TW)

(21) Appl. No.: 12/879,426

(22) Filed: Sep. 10, 2010

(30) Foreign Application Priority Data
Sep. 10, 2009 (CN) 200920169522.9

(51) Int. Cl. H05K 7/00; F16M 13/00

(52) U.S. Cl. 361/679.01; 248/346.03

(57) ABSTRACT

An engageable structure and an engageable electronic apparatus with such engageable structure are disclosed. The engageable structure includes a housing and a support. The housing has a first hole and a second hole. The first hole defines therein a first position and a second position, and the second hole defines therein a third position and a fourth position. The second position corresponds to the third position. The support includes a first pivot section and a second pivot section for fastening on a first coupling unit and a second coupling unit respectively. When the first and the second coupling unit are pivotably coupled to the first hole and the second hole respectively and then moved into the second position and the third position respectively, the support and the housing are engaged.

### FIELD OF THE INVENTION

The present invention relates to an engageable structure, and more particularly to an engageable structure that enables two parts to be firmly engaged and quickly detached from each other. The present invention also relates to an engageable electronic apparatus using such engageable structure.

### BACKGROUND OF THE INVENTION

In recent years, the market demands for various types of point-of-sale (POS) terminals present stable growth. In shopping malls, department stores and convenient chain stores, at least one set of the most frequently seen POS terminals, such as a cash register, is arranged at every check-out stand.

However, the POS terminals currently available in the market usually have a fixed support. When a user wants to install a POS terminal, the support must be directly inserted into a main body of the POS terminal and then be locked in place using other auxiliary parts, such as screws. Moreover, when the user wants to move or dismount the POS terminal, related tools must be used to assist in separation of the fixed support from the main body. Therefore, the conventional POS terminals are inconvenient for use.

It is therefore tried by the inventor to develop an improved engageable structure and an engageable electronic apparatus using same to overcome the above problems.

### SUMMARY OF THE INVENTION

An object of the present invention is to provide an engageable structure, so that an electronic device, such as a POS terminal, with such engageable structure can be conveniently moved or dismounted without the need for using any related tool to separate its fixed support from a main body thereof.

Another object of the present invention is to provide an engageable electronic apparatus having the above-mentioned engageable structure, so that the engageable electronic apparatus, which can be, for example, a POS terminal, can be conveniently moved or dismounted without the need for using any related tool to separate its electronic device from a supporting base thereof.

According to an embodiment of the present invention, the engageable structure includes a housing and a support. The housing has a first hole and a second hole, wherein the first hole defines a first position and a second position in the first hole, the second hole defines a third position and a fourth position in the second hole, and the second position corresponds to the third position. The support includes a first pivot section and a second pivot section, wherein the first pivot section has a plurality of first sunken holes for fastening on a first coupling unit, and the second pivot section has a plurality of second sunken holes for fastening on a second coupling unit. When the first pivot section and the second pivot section fasten on the first coupling unit and the second coupling unit respectively, and the first coupling unit and the second coupling unit are pivotably coupled to the first hole and the second hole respectively and then moved into the second position and the third position respectively, the support and the housing are engaged.

According to another embodiment of the present invention, the engageable electronic apparatus includes a supporting base and an electronic device. The supporting base has a first hole and a second hole, wherein the first hole defines a first position and a second position in the first hole, the second hole defines a third position and a fourth position in the second hole, and the second position corresponds to the third position. The electronic device includes a first pivot section and a second pivot section, wherein the first pivot section has a plurality of first sunken holes for fastening on a first coupling unit, and the second pivot section has a plurality of second sunken holes for fastening on a second coupling unit. When the first pivot section and the second pivot section fasten on the first coupling unit and the second coupling unit respectively, and the first coupling unit and the second coupling unit are pivotably coupled to the first hole and the second hole respectively and then moved into the second position and the third position respectively, the electronic device and the supporting base are engaged.

In conclusion, with the engageable structure and the engageable electronic apparatus provided by the present invention, two separate parts can be tightly engaged to each other and easily detached from each other through disposing the coupling units provided on one part into corresponding holes provided on the other part without the need for using additional auxiliary elements, such as screws, insertion pins or hinges. Therefore, with the present invention, it is possible to largely reduce the production cost as well as the labor and time needed to assemble the parts, making the products more competitive in the market.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a schematic view of an engageable structure according to an embodiment of the present invention;

FIG. 2 is an exploded perspective view of a first pivot section of a support for the engageable structure of FIG. 1;

FIG. 3A shows two figure-8-shaped holes on a housing of the engageable structure and two coupling units of the support before the holes and the coupling units are coupled;

FIG. 3B shows the two figure-8-shaped holes on the housing and the two coupling units of the support after the holes and the coupling units are coupled;

FIG. 4 is a schematic view of an engageable electronic apparatus according to an embodiment of the present invention;

FIG. 5 is an exploded perspective view of a first pivot section for the engageable electronic apparatus of FIG. 4;

FIG. 6A shows two holes on a supporting base of the engageable electronic apparatus and two coupling units on an electronic device before the holes and the coupling units are coupled;

FIG. 6B shows the two holes on the supporting base and the two coupling units of the two coupling units after the holes and the coupling units are coupled.

### DETAILED DESCRIPTION OF THE PREFERRED EMBODIMENTS

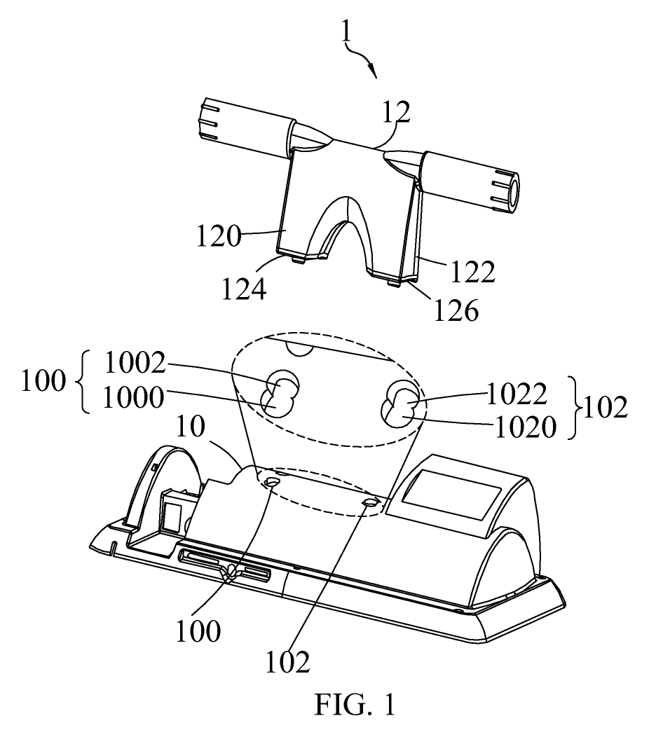

FIG. 1 is a schematic view of an engageable structure 1 according to an embodiment of the present invention. As shown in FIG. 1, the engageable structure 1 includes a housing 10 and a support 12. The housing used in the invention can take the usual meanings of the word “housing.” In the illustrated embodiment, the housing 10 may be provided for accommodating a plurality of electronic circuits of a POS terminal and may comprise an expansion port exposed for adding an expansion device. The housing further has a first figure-8-shaped hole 100 and a second figure-8-shaped hole 102. Hereinafter, the first figure-8-shaped hole 100 and the second figure-8-shaped hole 102 are called the first hole 100 and the second hole 102 respectively for short. The hole 100 further defines a first position 1000 and a second position 1002 in the first hole 100; and the hole 102 further defines a third position 1020 and a fourth position 1022 in the second hole 102.

More particularly, the housing 10 can have at least one first hole 100 and at least one second hole 102; and the first holes 100 and the second holes 102 are provided in pairs. In practical application, the provision of the holes is helpful in the adjustment of the position of the support 12 relative to the housing 10. Thus, in practical design, the distribution and the number of the holes on the housing 10 can be properly adjusted according to the size of the housing 10 and the user's actual requirements.

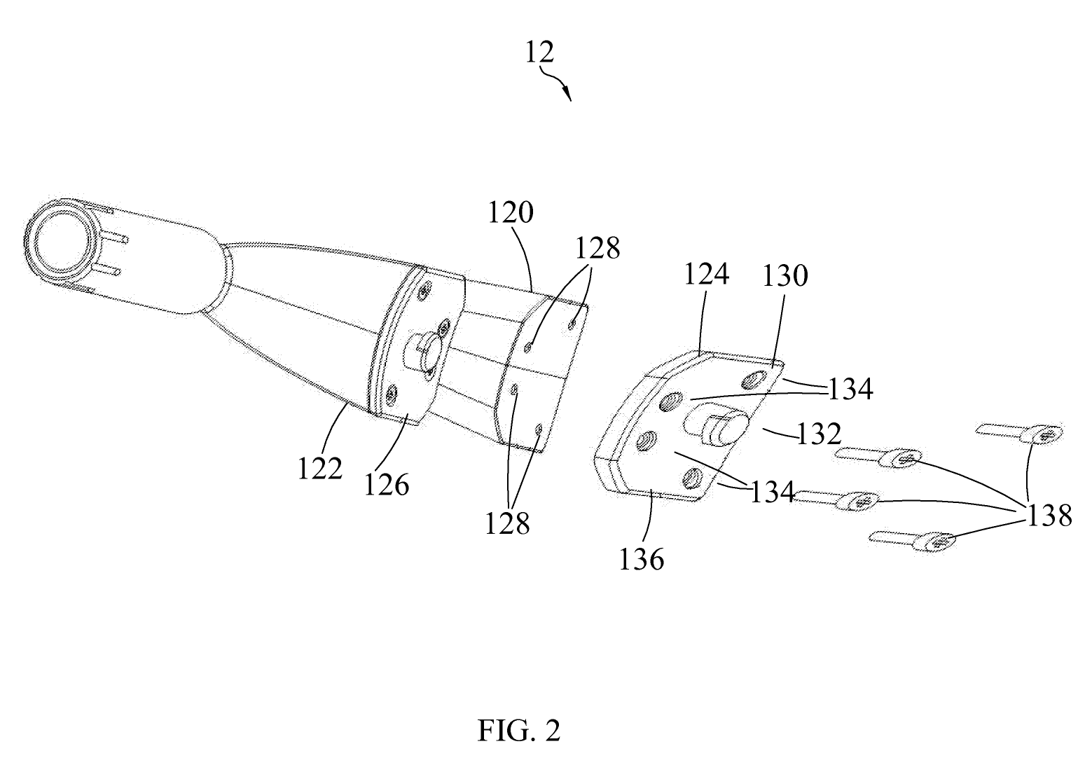

In the illustrated embodiment, the support 12 includes a first pivot section 120 and a second pivot section 122. In practical implementation, since the first and the second pivot sections 120, 122 are very similar in structure, they can be advantageously mass-produced. FIG. 2 is an exploded view of the first pivot section 120 of the support 12 shown in FIG. 1. As shown in FIG. 2, the first pivot section 120 has a plurality of first sunken holes 128 for fastening on a first coupling unit 124; and the second pivot section 122 has a plurality of second sunken holes (not shown) for fastening on a second coupling unit 126.

In practical application, since the first and the second coupling units 124, 126 are very similar in structure, only the first coupling unit 124 will be described with reference to FIG. 2 herein. In the illustrated embodiment, the first coupling unit 124 comprises a member 130 and a coupling member 132. The member 130 is capable of fitting the housing 10 and has a plurality of threaded holes 134. Accordingly the member 130 can be called a fitting member. The member 130 may e.g. be elastic and have a curved surface, as in the illustrated embodiment. The fitting member 130 of the first coupling unit 124 is used for fastening on the first pivot section 120, and the fitting member 130 of the second coupling unit 126 is used for fastening on the second pivot section 122. In practical application, since the fitting member 130 must be produced with its curvature matching that of the housing 10, the fitting member 130 can also be a plane surface, depending on actual need.

In the illustrated embodiment, the coupling member 132 is integrally formed on the fitting member 130 in the course of manufacturing. The coupling members 132 of the first coupling unit 124 and the second coupling unit 126 have a function of being detachably coupled to the first hole 100 and the second hole 102. It is particularly noted the coupling member 132 of the first coupling unit 124 and the coupling member 132 of the second coupling unit 126 should be arranged in such a way that they are oriented toward two opposite directions, in order to match the disposition of the holes.

A plurality of fastening element 138 is provided corresponding to the threaded holes 134 on the fitting members 130; and the fastening elements 138 are separately inserted through the threaded holes 134 into the first sunken holes 128 on the first pivot section 120 and the second sunken holes (not shown) on the second pivot section 122 to thereby firmly fasten the first and second coupling units 124, 126 to the first pivot section 120 and the second pivot section 122, respectively. At this point, the elastic fitting members 130 are deformed for the first coupling unit 124 and the second coupling unit 126 to more tightly fasten on the first pivot section 120 and the second pivot section 122, respectively. In practical implementation, the fastening elements 138 can include, without being limited to, screws, insertion pins, or the like.

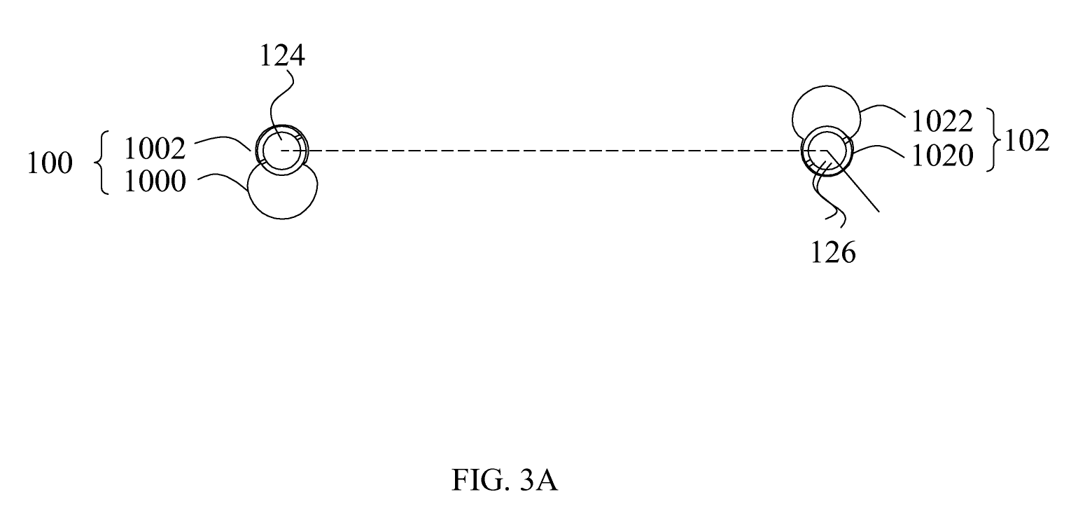

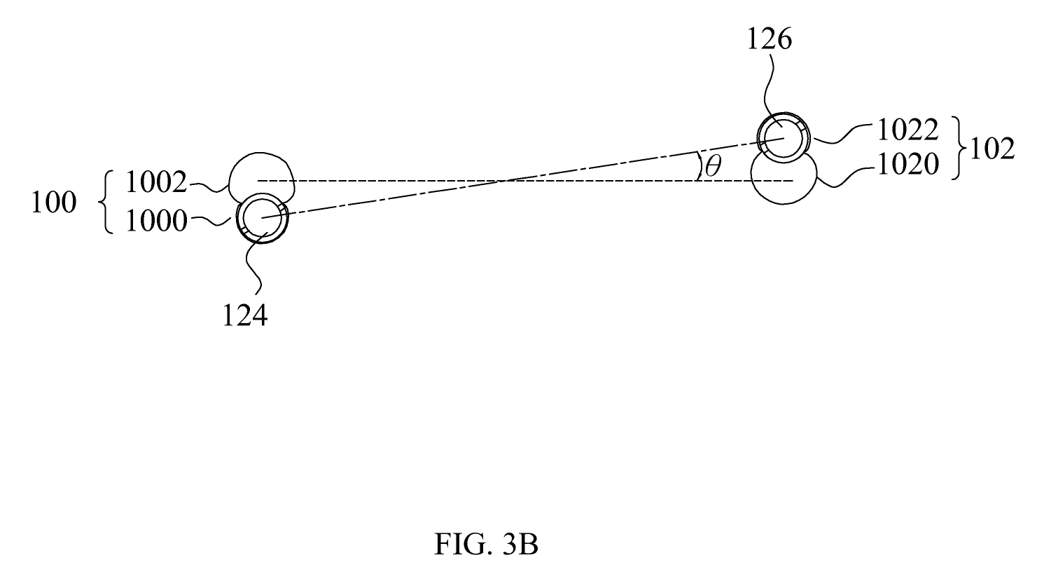

FIG. 3A schematically shows the holes 100, 102 on the housing 10 and the coupling units 124, 126 before the holes and the coupling units are coupled. The first coupling unit 124 and the second coupling unit 126 have a function of being pivotably coupled to the first hole 100 and the second hole 102, respectively, and the second position 1002 corresponds to the third position 1020. When the first coupling unit 124 and the second coupling unit 126 are respectively disposed in the first position 1000 of the first hole 100 and the fourth position 1022 of the second hole 102 at an oblique angle relative to a line extended between the second position 1002 and the third position 1020, the housing 10 and the support 12 are not yet engaged.

FIG. 3B schematically shows the holes 100, 102 on the housing 10 and the coupling units 124, 126 after the holes and the coupling units are coupled. As shown in FIG. 3B, when the support 12 is rotated relative to the housing 10 by an angle θ for the first coupling unit 124 to move into the second position 1002 of the first hole 100 and the second coupling unit 126 into the third position 1020 of the second hole 102, the housing 10 and the support 12 will become engaged.

In the illustrated embodiment, the support 12 can engage with the housing 10 by rotating the support 12 clockwise by an angle θ relative to the housing 10. In other words, the support 12 can be easily separated from the housing 10 simply by rotating the support 12 counterclockwise.

In practical application, the housing 10 can include an electronic device, such as a main system of a calculator or other types of POS (point-of-sale) terminals. Further, the housing 10 can include some specific areas, at where input interfaces of the electronic device are exposed to a surface of the housing 10, allowing a user to, for example, conveniently expand the storage device of or add a new input device to the electronic device. Therefore, in practical implementation, the housing 10 and the specific areas may respectively have a different appearance and the specific areas may be arranged on the housing 10 at other suitable positions without being particularly restricted to those as shown in FIG. 1. The housing 10 and the specific areas can be designed according to the user's requirements. Moreover, the support 12 is used to support a display unit. The display unit can be, without being limited to, such as a display or a touchscreen.

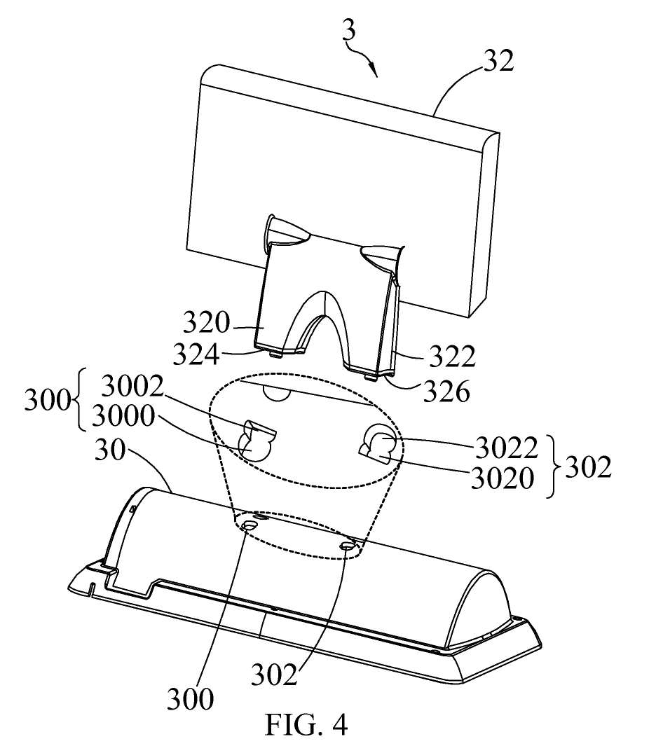

In FIG. 4, an engageable electronic apparatus 3 according to an embodiment of the present invention is shown. In practical applications, the engageable electronic apparatus 3 can be any type of POS terminal or a monitor. As can be seen from FIG. 4, the engageable electronic apparatus 3 includes a supporting base 30 and an electronic device 32.

In the illustrated embodiment, the supporting base 30 has a first hole 300 and a second hole 302. The first hole 300 defines a first position 3000 and a second position 3002 in the first hole 300; and the second hole 302 defines a third position 3020 and a fourth position 3022 in the second hole 302. The supporting base 30 has a curved outer surface, and has at least one first hole 300 and at least one second hole 302. The first holes 300 and the second holes 302 are arranged on the surface of the supporting base 30 in pairs. In practical applications, the electronic device 32 can be adjusted in position via the distribution of the first and second holes 300, 302 on the supporting base 30, allowing a user to operate the electronic device 32 in a more convenient manner. In the illustrated embodiment, the first hole 300 and the second hole 302 are not particularly restricted any specific shape, compared to the above-mentioned holes 100, 102. Therefore, the present invention is not limited by the description herein.

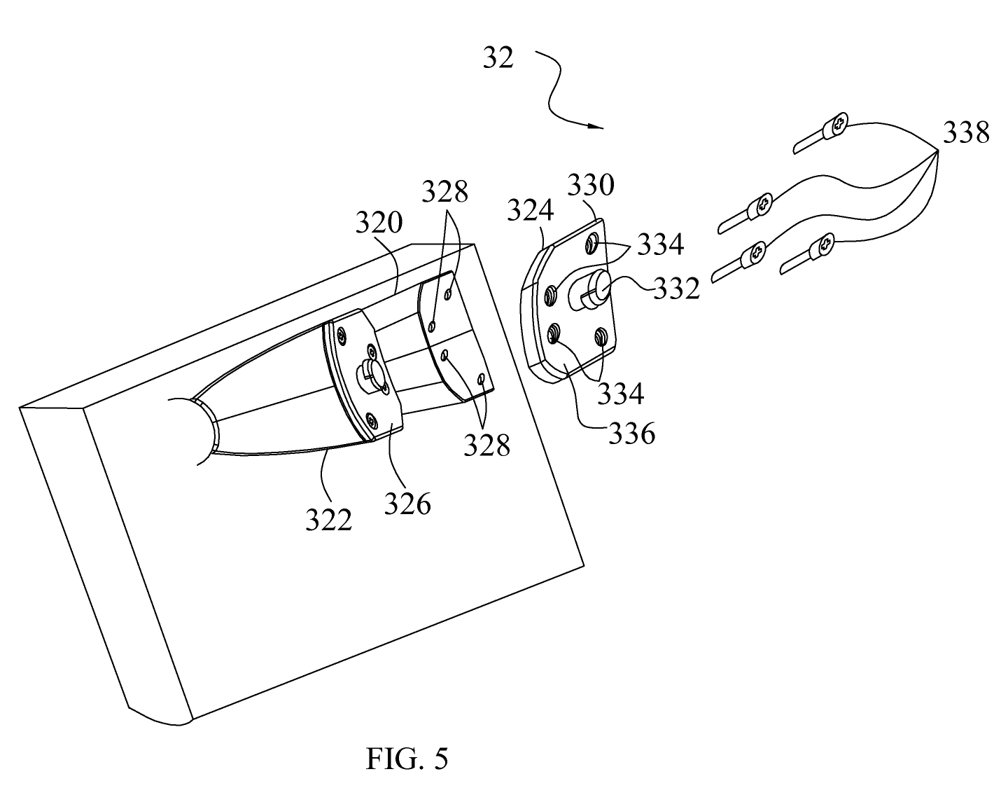

The electronic device 32 includes a first pivot section 320 and a second pivot section 322. FIG. 5 is an exploded view of the first pivot section 320 of the electronic device 32 shown in FIG. 4. As shown in FIG. 5, the first pivot section 320 has a plurality of first sunken holes 328 for fastening on a first coupling unit 324; and the second pivot section 322 has a plurality of second sunken holes (not shown) for fastening on a second coupling unit 326. In practical implementation, since the first and the second pivot sections 320, 322 are very similar in structure, they can be advantageously mass-produced.

In practical applications, since the first and the second coupling units 324, 326 are very similar in structure, only the first coupling unit 324 will be described with reference to FIG. 5 herein. In the illustrated embodiment, the first coupling unit 324 includes a member 330 and a coupling member 332. The member 330 is capable of fitting the supporting base 30, and has a plurality of threaded holes 334. Accordingly the member 330 can be called a fitting member. The member 330 may be elastic and have a curved surface, as in the illustrated embodiment. The fitting member 330 of the first coupling unit 324 is used for fastening on the first pivot section 320, and the fitting member 330 of the second coupling unit 326 is used for fastening on the second pivot section 322. Since the fitting members 330 each has a curvature provided in a manner similar to that of the fitting members 130 as described above with reference to FIG. 2, they are not described repeatedly herein.

The coupling member 332 is integrally formed on the fitting member 330 in the course of manufacturing. Since the coupling members 332 are arranged in a manner similar to the coupling members 132 as described above with reference to FIG. 2, they are not described repeatedly herein. The coupling members 332 of the first coupling unit 324 and the second coupling unit 326 have a function of being detachably coupled to the first hole 300 and the second hole 302.

In the illustrated embodiment, a plurality of fastening element 338 is provided corresponding to the threaded holes 334 on the fitting members 330; and the fastening elements 338 are separately inserted through the threaded holes 334 into the first sunken holes 328 on the first pivot section 320 and the second sunken holes (not shown) on the second pivot section 322 to thereby firmly fasten the coupling units 324, 326 to the first pivot section 320 and the second pivot section 322, respectively. At this point, the elastic fitting members 330 are deformed for the first coupling unit 324 and the second coupling unit 326 to more tightly fasten on the first pivot section 320 and the second pivot section 322, respectively.

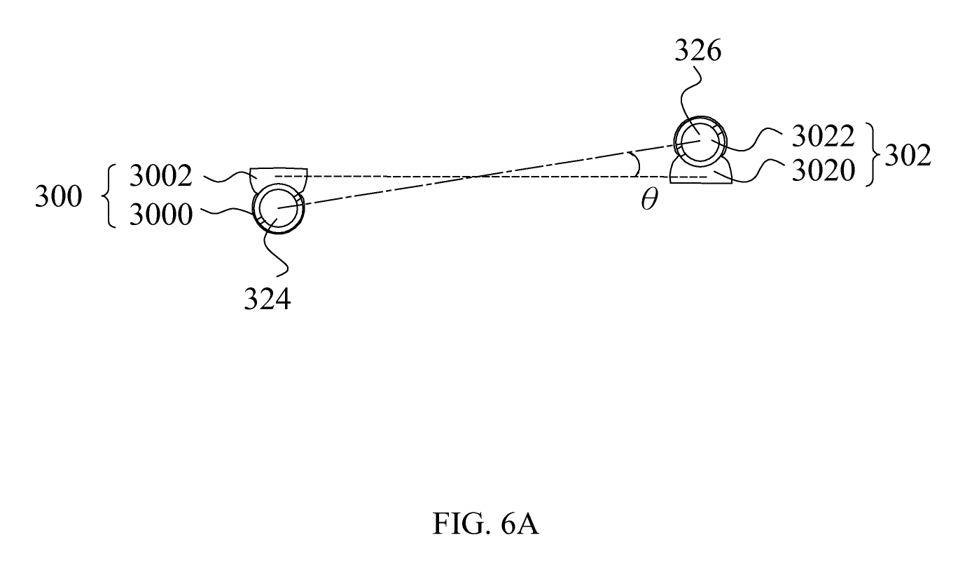

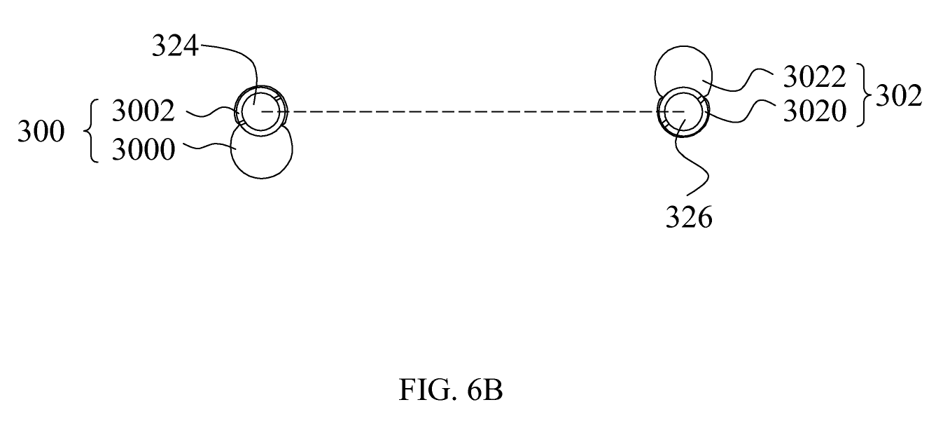

FIG. 6A shows the situation when the first coupling unit 324 and the second coupling unit 326 are not coupled to the first hole 300 and the second 302 respectively, and FIG. 6B shows the situation when the first coupling unit 324 and the second coupling unit 326 are coupled to the first hole 300 and the second 302 respectively. Specifically FIG. 6A schematically shows the holes 300, 302 on the supporting base 30 and the coupling units 324, 326 before the holes and the coupling units are coupled, and FIG. 6B schematically shows the holes 300, 302 on the supporting base 30 and the coupling units 324, 326 after the holes and the coupling units are coupled. As shown in FIG. 6A, the second position 3002 corresponds to the third position 3020. When the first coupling unit 324 and the second coupling unit 326 are respectively disposed in the first position 3000 of the first hole 300 and the fourth position 3022 of the second hole 302, it means the supporting base 30 and the electronic device 32 are not yet engaged. At this point, when the electronic device 32 is rotated clockwise relative to the supporting base 30 by an angle θ for the first coupling unit 324 to move into the second position 3002 of the first hole 300 and the second coupling unit 126 into the third position 3020 of the second hole 302, the supporting base 30 and the electronic device 32 will become engaged. In other words, the electronic device 32 can be easily separated from the supporting base 30 simply by rotating the electronic device 32 counterclockwise by the same angle θ.

In conclusion, with the engageable structure and the engageable electronic apparatus provided by the present invention, two separate parts can be tightly engaged and easily detached from each other through disposing the coupling units on one part into corresponding holes on the other part without the need for using additional auxiliary elements, such as screws, insertion pins or hinges. Therefore, with the present invention, it is possible to largely reduce the production cost as well as the labor and time needed to assemble the parts, making the products more competitive in the market.

The present invention has been described with some preferred embodiments thereof and it is understood that many changes and modifications in the described embodiments can be carried out without departing from the scope and the spirit of the invention that is intended to be limited only by the appended claims.

What is claimed is:

1. An engageable structure, comprising:
a housing having a first hole and a second hole, the first hole defining therein a first position and a second position, the second hole defining therein a third position and a fourth position, the second position corresponding to the third position; and
a support comprising:
a first pivot section having a plurality of first sunken holes for fastening on a first coupling unit; and
a second pivot section having a plurality of second sunken holes for fastening on a second coupling unit;
wherein when the first pivot section and the second pivot section fasten on the first coupling unit and the second coupling unit respectively, and the first coupling unit and the second coupling unit are pivotably coupled to the first hole and the second hole respectively and then moved into the second position and the third position respectively, the support and the housing are engaged.

2. The engageable structure as claimed in claim 1, wherein the support is separable from the housing when the first coupling unit and the second coupling unit are moved into the first position and the fourth position, respectively.

3. The engageable structure as claimed in claim 2, wherein the support and the housing are engaged or separated from each other by rotating the support by an angle relative to the housing.

4. The engageable structure as claimed in claim 1, wherein the first coupling unit and the second coupling unit each includes:
a member capable of fitting the housing, and having threaded holes, the fitting member of the first coupling unit being used for fastening on the first pivot section, the fitting member of the second coupling unit being used for fastening on the second pivot section; and
a coupling member disposed on the fitting member, the coupling member of the first coupling unit having a function of being coupled to the first hole, the coupling member of the second coupling unit having a function of being coupled to the second hole.

5. The engageable structure as claimed in claim 4, with fastening elements inserted through the threaded holes, the first sunken holes and the second sunken holes for fastening the first coupling unit and the first pivot section, and fastening the second coupling unit and the second pivot section.

6. The engageable structure as claimed in claim 1, wherein the support is used to support a display unit.

7. The engageable structure as claimed in claim 1, wherein the housing has at least a pair of the first hole and the second hole.

8. The engageable structure as claimed in claim 1, wherein the housing has an expansion port exposed for adding an expansion device.

9. The engageable structure as claimed in claim 1, wherein the housing includes an electronic device.

10. An engageable electronic apparatus, comprising:
a supporting base having a first hole and a second hole, the first hole defining therein a first position and a second position, the second hole defining therein a third position and a fourth position, the second position corresponding to the third position; and
an electronic device comprising:
a first pivot section having a plurality of first sunken holes for fastening on a first coupling unit; and
a second pivot section having a plurality of second sunken holes for fastening on a second coupling unit;
wherein when the first pivot section and the second pivot section fasten on the first coupling unit and the second coupling unit respectively, and the first coupling unit and the second coupling unit are pivotably coupled to the first hole and the second hole respectively and then moved into the second position and the third position respectively, the electronic device and the supporting base are engaged.

11. The engageable electronic apparatus as claimed in claim 10, wherein the electronic device is separable from the supporting base when the first coupling unit and the second coupling unit are moved into the first position and the fourth position, respectively.

12. The engageable electronic apparatus as claimed in claim 11, wherein the electronic device and the supporting base are engaged or separated from each other by rotating the electronic device by an angle relative to the supporting base.

13. The engageable electronic apparatus as claimed in claim 10, wherein the first coupling unit and the second coupling unit each includes:
a member capable of fitting the supporting base, and having threaded holes, the fitting member of the first coupling unit being used for fastening on the first pivot section, the fitting member of the second coupling unit being used for fastening on the second pivot section; and
a coupling member disposed on the fitting member, the coupling member of the first coupling unit having a function of being coupled to the first hole, the coupling member of the second coupling unit having a function of being coupled to the second hole.

14. The engageable electronic apparatus as claimed in claim 13, with fastening elements inserted through the threaded holes, the first sunken holes and the second sunken holes for fastening the first coupling unit and the first pivot section, and fastening the second coupling unit and the second pivot section.

15. The engageable electronic apparatus as claimed in claim 10, wherein the supporting base has at least a pair of the first hole and the second hole.
